(19) United States
(12) Patent Application Publication
(10) Pub. No.: US 2015/0206829 A1
(43) Pub. Date: Jul. 23, 2015

(54) SEMICONDUCTOR PACKAGE WITH INTERIOR LEADS

(71) Applicants: Yin Kheng Au, Petaling Jaya (MY); Seoh Hian Teh, Taman Damai Impian (MY); Jia Lin Yap, Klang (MY); Pey Fang Hiew, Kajang (MY); Ly Hoon Khoo, Bandar Puteri Klang (MY)

(72) Inventors: Yin Kheng Au, Petaling Jaya (MY); Seoh Hian Teh, Taman Damai Impian (MY); Jia Lin Yap, Klang (MY); Pey Fang Hiew, Kajang (MY); Ly Hoon Khoo, Bandar Puteri Klang (MY)

(21) Appl. No.: 14/157,536

(22) Filed: Jan. 17, 2014

(51) Int. Cl. H01L 23/495; H01L 23/31

(52) U.S. Cl. CPC H01L 23/4952; H01L 23/49541; H01L 23/3114

(57) ABSTRACT

A packaged semiconductor device has a lead frame, a semiconductor die, and bond wires. The lead frame has a two-dimensional array of leads with a subset of interior leads located in the interior of the array that do not extend to the perimeter of the array. The bond wires are connected to the semiconductor die and respective ones of the leads of the array.

### BACKGROUND

The present invention relates generally to semiconductor packaging, and, more particularly, to lead frame based semiconductor devices.

Certain semiconductor packages having planar leads (i.e., flat pins or pads having flat mating surfaces), such as quad-flat packages (QFPs), quad-flat no-lead (QFN) packages, and dual-flat no-lead (DFN) packages, are typically assembled by (i) attaching a semiconductor die to a lead frame, (ii) electrically connecting the semiconductor die with bond wires to leads of the lead frame, and (iii) encapsulating the semiconductor die, the bond wires, and at least the top of the lead frame with a molding compound.

These types of packages typically have leads around their perimeters or that project from the sides of the package body. To increase the number of leads, the size and spacing of the leads may be decreased. However, as the leads are spaced closer together, undesirable solder bridges become more likely, putting higher demands on the soldering process and alignment of parts during assembly. Therefore, the number of leads that may be implemented in a package having flat leads is typically limited based on the size of the package.

Accordingly, it would be advantageous to have semiconductor packages that employ greater numbers of flat leads than that of comparably-sized conventional flat-lead packages.

### BRIEF DESCRIPTION OF THE DRAWINGS

Embodiments of the present invention are illustrated by way of example and are not limited by the accompanying figures, in which like references indicate similar elements. Elements in the figures are illustrated for simplicity and clarity and have not necessarily been drawn to scale. For example, the thicknesses of layers and regions may be exaggerated for clarity.

FIG. 1 shows top and cross-sectional views of a lead frame panel according to one embodiment of the present invention;

FIG. 2 shows a simplified flow diagram of a process for assembling one or more surface-mount packages according to one embodiment of the present invention;

FIG. 3 shows various views of some of the assembly steps of the process of FIG. 2;

FIG. 4 shows a cross-sectional view of a surface-mount package according to another embodiment of the present invention;

FIG. 5 shows a cross-sectional view of a surface-mount package according to yet another embodiment of the present invention;

FIG. 6 shows a simplified flow diagram of a process for assembling one or more lead frames according to one embodiment of the present invention;

FIG. 7 shows various views of some of the assembly steps of the process of FIG. 6;

FIG. 8 shows a simplified flow diagram of a process for assembling one or more surface-mount packages according to another embodiment of the present invention;

FIG. 9 shows a top view of a lead frame according to one embodiment of the present invention;

FIG. 10 shows various views of some of the assembly steps of the process of FIG. 8;

FIG. 11 shows a simplified flow diagram of a process for assembling one or more surface-mount packages according to yet another embodiment of the present invention; and

FIG. 12 shows various views of some of the assembly steps of the process of FIG. 11.

### DETAILED DESCRIPTION

Detailed illustrative embodiments of the present invention are disclosed herein. However, specific structural and functional details disclosed herein are merely representative for purposes of describing example embodiments of the present invention. Embodiments of the present invention may be embodied in many alternative forms and should not be construed as limited to only the embodiments set forth herein. Further, the terminology used herein is for the purpose of describing particular embodiments only and is not intended to be limiting of example embodiments of the present invention.

As used herein, the singular forms “a,” “an,” and “the,” are intended to include the plural forms as well, unless the context clearly indicates otherwise. It further will be understood that the terms “comprises,” “comprising,” “has,” “having,” “includes,” and/or “including” specify the presence of stated features, steps, or components, but do not preclude the presence or addition of one or more other features, steps, or components. It also should be noted that, in some alternative implementations, the functions/acts noted may occur out of the order noted in the figures. For example, two figures shown in succession may in fact be executed substantially concurrently or may sometimes be executed in the reverse order, depending upon the functionality/acts involved.

In one embodiment of the present invention, a packaged semiconductor device comprises a lead frame, a semiconductor die, and at least one bond wire. The lead frame comprises a two-dimensional array of leads having a subset of interior leads located in the interior of the array that do not extend to the perimeter of the array. The at least one bond wire is wire-bonded to the semiconductor die and to one of the leads of the array.

In another embodiment of the present invention, a packaged semiconductor device comprises a quad-flat no-leads lead frame, an array lead frame, a semiconductor die, at least one bond wire, and at least one other bond wire. The quad-flat no-leads lead frame comprises perimeter leads that extend to a perimeter of the quad-flat no-leads lead frame. The array lead frame comprises a two-dimensional array of interior leads that do not extend to the perimeter of the quad-flat no-leads lead frame. The semiconductor die is mounted over one or more of the leads in the two-dimensional array of leads. The at least one bond wire is wire-bonded to the semiconductor die and to one of the interior leads. The at least one other bond wire is wire-bonded to the semiconductor die and to one of the perimeter leads.

In yet another embodiment of the present invention, a packaged semiconductor device comprises a quad-flat package lead frame, an array lead frame, a semiconductor die, at least one bond wire, and at least one other bond wire. The quad-flat package lead frame comprises perimeter leads that extend to a perimeter of the quad-flat package lead frame and a die paddle. The array lead frame comprises a two-dimensional array of interior leads, wherein the interior leads do not extend to the perimeter of the quad-flat package lead frame. The semiconductor die is mounted over the die paddle. The at least one bond wire is attached to the semiconductor die and to one of the interior leads. The at least one other bond wire is attached to the semiconductor die and to one of the perimeter leads.

Lead frames of the present invention may be fabricated individually or together with other lead frames on what is referred to herein as a “lead frame panel.” The lead frame panel is a structure that comprises a plurality of instances of adjoined lead frames that may be detached from one another using processing such as saw singulation.

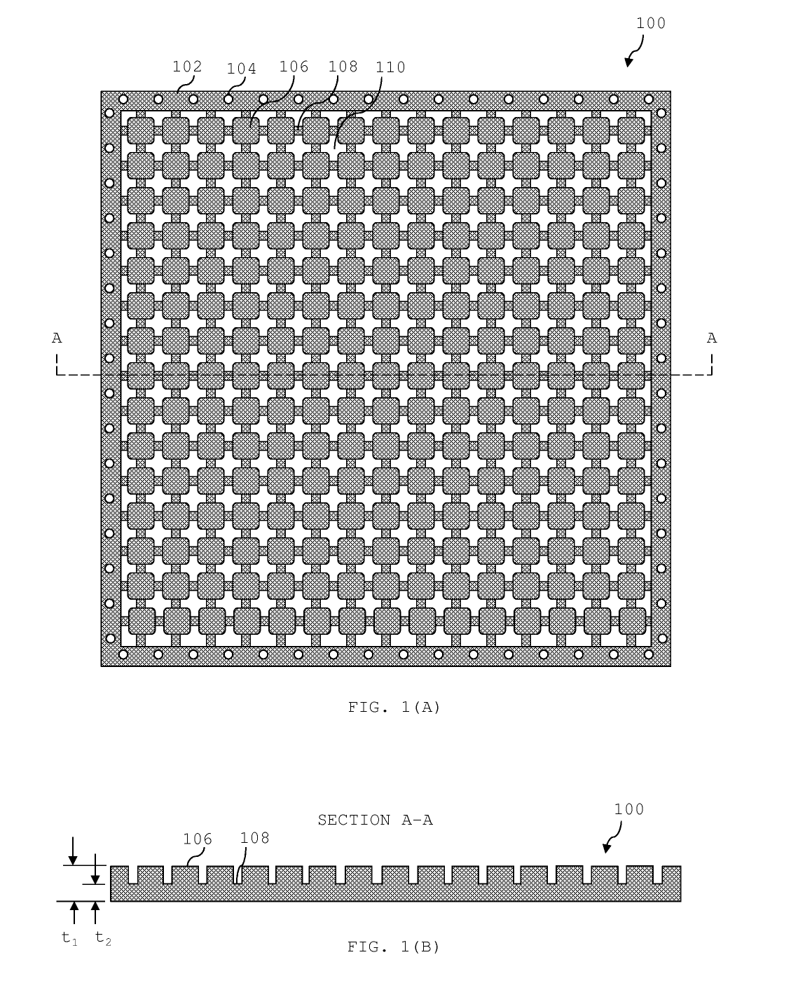

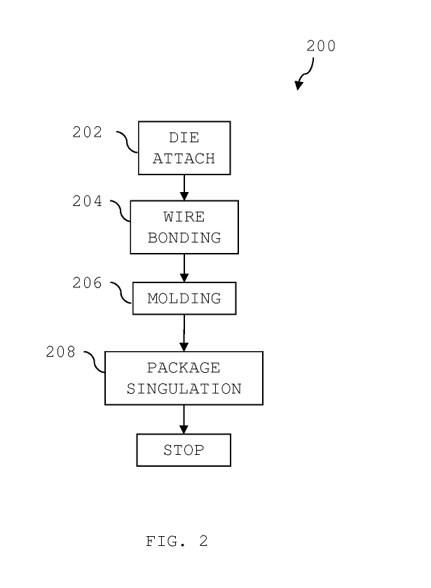

FIG. 1(A) shows a top view of a lead frame panel 100 according to one embodiment of the present invention, and FIG. 1(B) shows a cross-sectional view A-A of the lead frame panel 100. In this embodiment, the lead frame panel 100 is fabricated from a single, square-shaped sheet of a suitable conducting metal or alloy such as (without limitation) copper. The lead frame panel 100 may be fabricated on a sheet with other lead frame panels (not shown) and detached therefrom using saw singulation, etching, or stamping.

The lead frame panel 100 comprises a metal border 102 and a two-dimensional array of substantially planar, substantially square-shaped, metal leads 106 arranged in 15 rows and 15 columns. The leads 106 are connected to adjacent leads and to the border 102 by metal connecting bars 108.

The pattern defined by the leads 106 and the connecting bars 108 may be formed by etching the metal sheet and/or stamping. In particular, the rows and columns of the leads 106 may be formed by etching holes 110 all the way through the metal sheet. As illustrated in FIG. 1(B), the thickness of the connecting bars 108 is reduced by etching part of the way through the connecting bars 108 such that the thickness t₂ of the connecting bars is less than the thickness t₁ of the leads 106.

A plurality of guide holes 104 are formed all the way through the border 102 using etching. The guide holes 104 are arranged in between the columns and rows of the leads 106. These guide holes 104 may be subsequently used as a guide for sawing (discussed below) to separate a plurality of lead frames from one another and to electrically isolate the leads 106 from one another (i.e., to cut the connecting bars 108).

As one example, the lead frame panel 100 may be cut into nine lead frames, where each lead frame has a 5×5 array of the leads 106. In each 5×5 array, 16 of the leads 106 lie along the perimeter of the lead frame and nine of the leads 106 do not extend to the perimeter of the lead frame (i.e., are entirely within the perimeter of the lead frame). Importantly, the interior leads 106 are not positioned between the perimeter leads 106 at all, and as a result, the interior leads 106 do not interfere with the spacing of the perimeter leads 106. Thus, the perimeter leads 106 can be placed as close to one another as reasonably practicable.

Lead frame panel 100 and other lead frame panels of the invention (which will become clearer in the following description) may be used for the assembly of surface-mount packages. As an example, consider FIG. 2.

FIG. 2 shows a simplified flow diagram of a process 200 for assembling one or more surface-mount packages according to one embodiment of the present invention. For this discussion, suppose that process 200 is used to assemble four surface-mount packages onto the lead frame panel 100 of FIG. 1, and that each of the four packages has one semiconductor die. At step 202, the four semiconductor dies are attached to the lead frame panel 100, and at step 204, the four dies are wire-bonded to the lead frame panel 100.

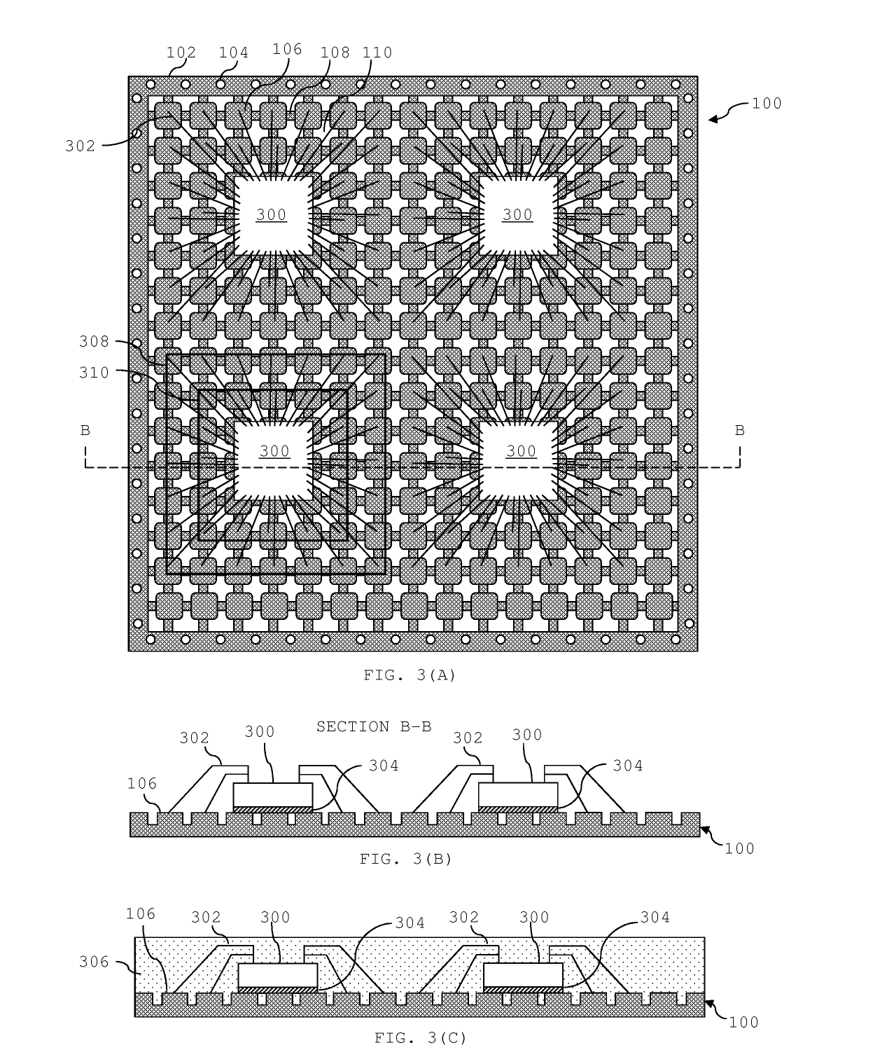

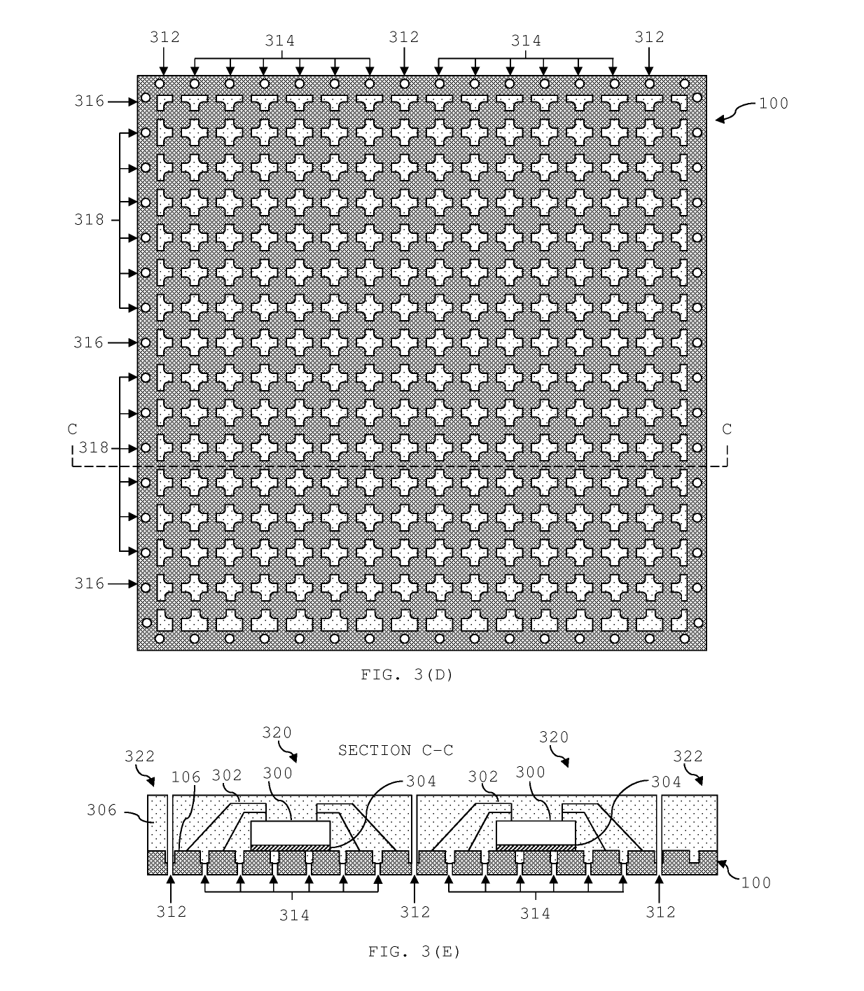

FIGS. 3(A) and 3(B) show a top view and a cross-sectional view B-B, respectively, of the lead frame panel 100 after die attachment and wire-bonding. As shown, each of the dies 300 is attached directly onto (e.g., mounted over) nine of the leads 106 using a die-attach film or epoxy 304. The nine leads 106 are inactive leads that essentially act as a die paddle and are not used for input or output connections.

Each of the dies 300 is wire-bonded with 40 bond wires 302 to the remaining 40 leads 106. The remaining 40 leads 106, which are active leads that may be used for input and/or output connections, form a pair of concentric squares, with the outer square 308 having 24 of the 40 leads 106 and the inner square 310 having 16 of the 40 leads 106.

Note that, to help facilitate the understanding of the present invention, the bond wires shown in the cross-sectional views of FIGS. 3(B), 3(C), and the figures that follow, are not shown as a true cross-section. In some views (e.g., FIG. 3(B)), fewer than all of the bond wires that would be visible in a true-cross section are shown, while in other figures (e.g., FIG. 3(C)), more bond wires are shown than would be visible in a true cross-section. Furthermore, although it may appear, in some views, that multiple bond wires are connected to the same pad on the die, in reality, no die pad has more than one bond wire connected to it.

After wire-bonding, molding compound 306 is applied in step 206 to encase the top of the lead frame panel 100, the dies 300, and the bond wires 302. FIG. 3(C) shows a cross-sectional view of the lead frame panel 100 after molding.

After molding, saw singulation is performed in step 208 using saw-guide holes 104 as a guide. FIG. 3(D) shows a bottom view of the lead frame panel 100 before saw singulation, and FIG. 3(E) shows a cross-sectional view of the lead frame panel 100 after saw singulation. To electrically de-couple the leads 106 from one another, partial sawing is performed on the bottom surface of lead frame panel 100 along columns 314 and rows 318. The partial sawing cuts entirely through the metal of the connecting bars 108 of the lead frame panel 100, and possibly part of the way, but not all the way, through the molding compound 306.

To separate the four individual surface-mount packages 320 from one another, sawing is performed all the way through (i) the lead frame panel 100 and (ii) the molding compound 306 along columns 312 and rows 316. This operation leads to some excess material 322 that may be discarded.

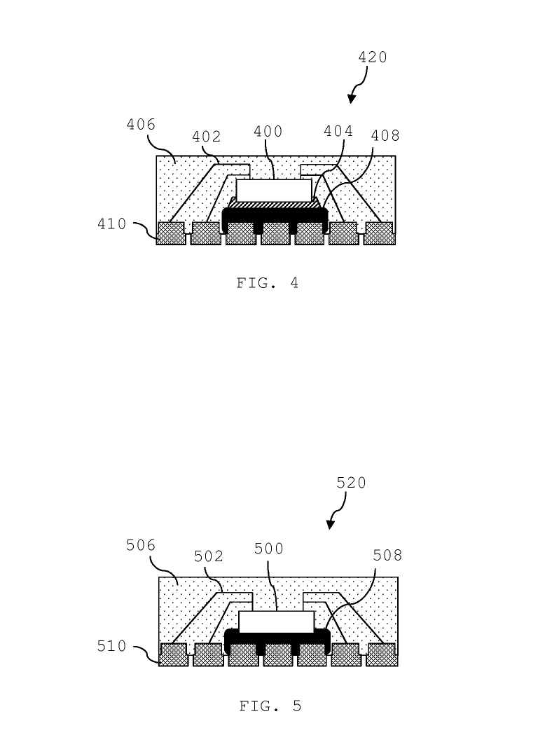

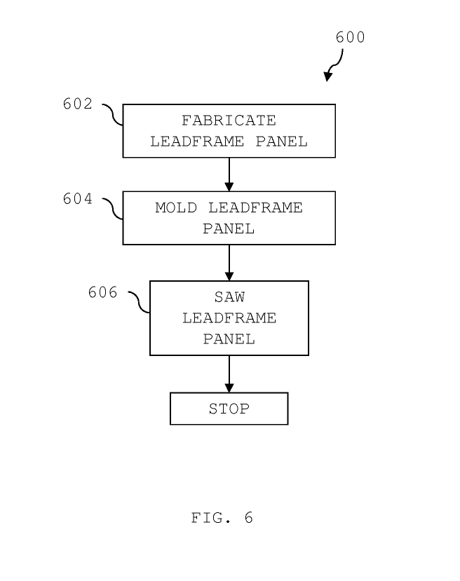

According to alternative embodiments of the present invention, the attachment of dies in step 202 may be performed using suitable techniques other than the technique described above. Two examples of such other suitable techniques are shown in FIGS. 4 and 5.

FIG. 4 shows a cross-sectional view of a surface-mount package 420 according to another embodiment of the present invention. The surface-mount package 420 is assembled in a manner similar to that of surface-mount package 320 of FIG. 3. However, in this embodiment, the die 400 is attached to the lead frame 410 by (i) applying a liquid encapsulant to the nine inactive leads (only three of which are shown) to form a die paddle 408 and (ii) attaching the die 400 to the die paddle 408 using a die-attach film or epoxy 404. After attaching the die 400, steps analogous to steps 204-208 of FIG. 2 are performed as described above to apply the bond wires 402 and the molding compound 406 and to complete the assembly of the surface-mount package 420.

FIG. 5 shows a cross-sectional view of a surface-mount package 520 according to yet another embodiment of the present invention. The surface-mount package 520 is also assembled in a manner similar to that of package 320 of FIG. 3. However, in this embodiment, the die 500 is attached to the lead frame 510 by (i) applying a liquid encapsulant to the nine inactive leads (only three of which are shown) to form a die paddle 508 and (ii) attaching the die 500 directly to the die paddle 508 before the liquid encapsulant solidifies so that the die 500 adheres to the liquid encapsulant. After attaching the die 500, steps analogous to steps 204-208 of FIG. 2 are performed as described above to apply the bond wires 502 and the molding compound 506 and to complete the assembly of the surface-mount package 520.

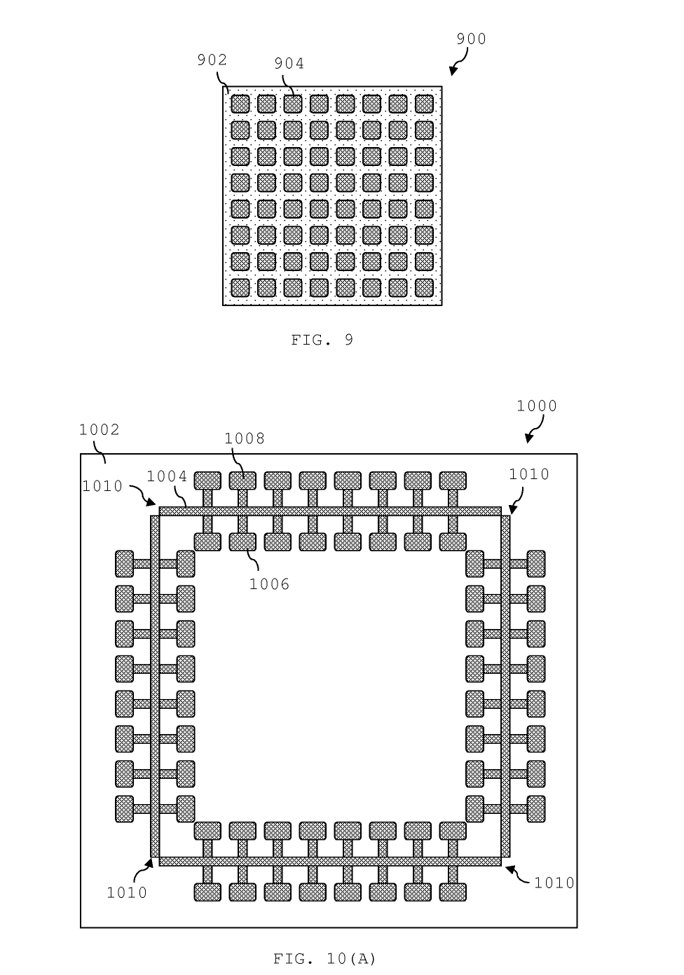

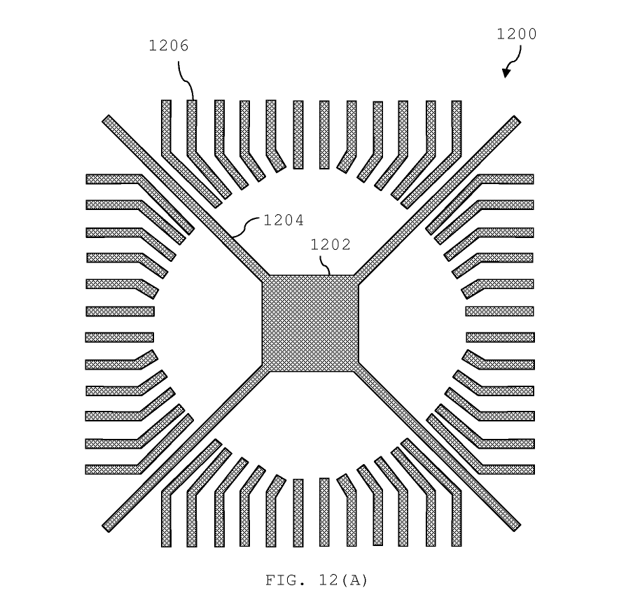

FIG. 6 shows a simplified flow diagram of a process 600 for fabricating one or more lead frames from a lead frame panel according to one embodiment of the present invention. As will be described in further detail below in relation to FIGS. 8 and 11, the lead frames fabricated by the process 600 may be combined with other lead frames to create new modified lead frames.

In step 602, a lead frame panel of the present invention, such as lead frame panel 100 of FIG. 1, is fabricated. For this discussion, suppose that lead frame panel 100 of FIG. 1 is used. Molding compound is applied to the lead frame panel 100 in step 604.

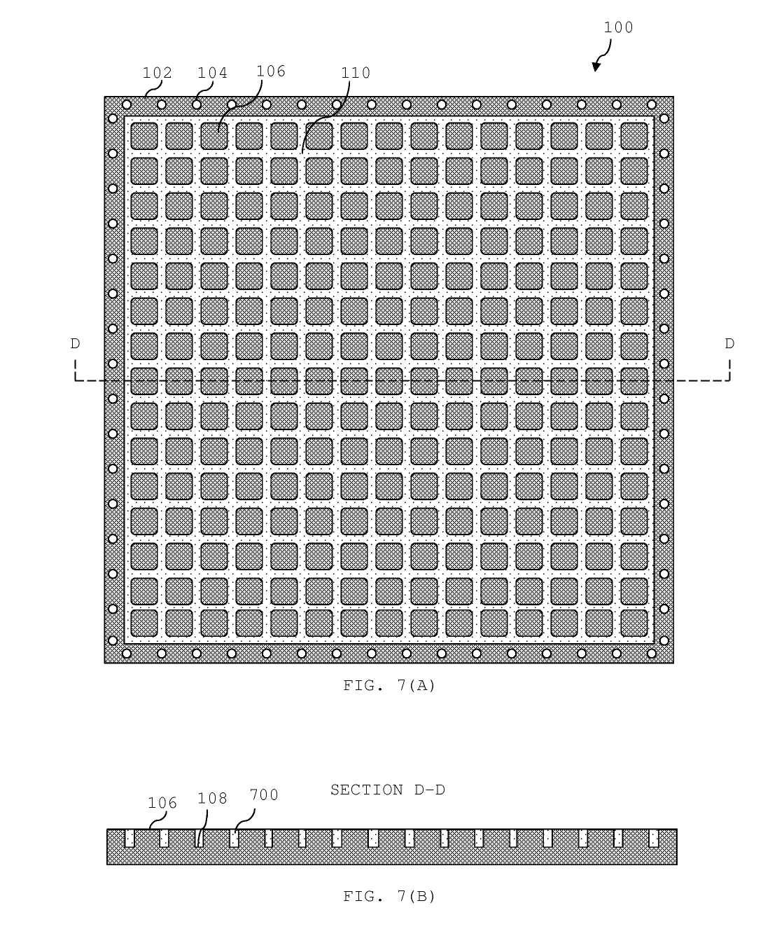

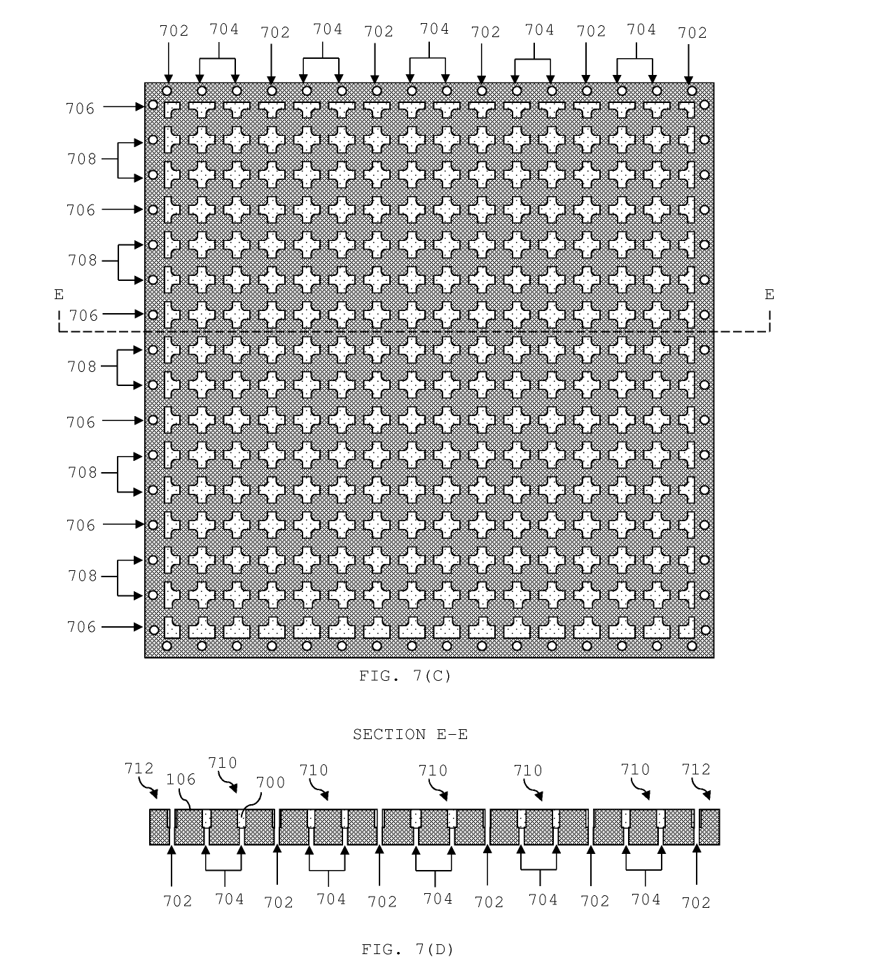

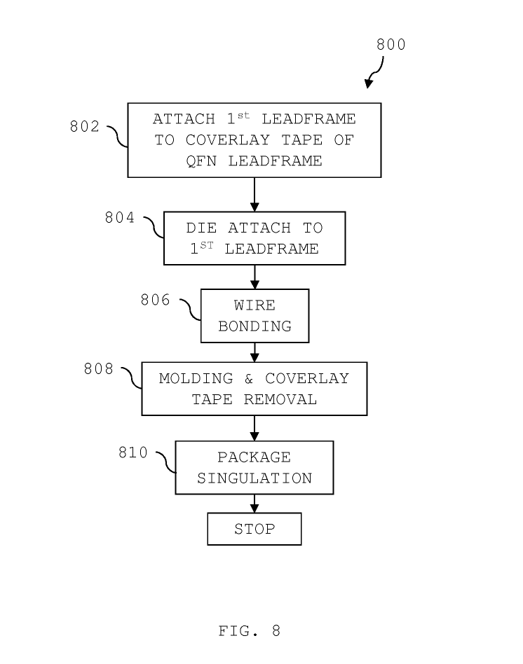

FIG. 7(A) shows a top view and FIG. 7(B) shows a cross-sectional view D-D of the lead frame panel 100 according to one embodiment of the present invention after a molding compound 700 has been applied. As shown, the molding compound 700 fills all of the spaces between adjacent leads 106 and between the leads 106 and the border 102. Further, the molding compound 700 fills the spaces above the connecting bars 108.

Referring back to FIG. 6, after molding, sawing is performed in step 606 to (i) electrically de-couple the leads 106 from one another and (ii) separate the individual lead frames.

FIG. 7(C) shows a bottom view of the lead frame panel 100 before saw singulation, and FIG. 7(D) shows a cross-sectional view E-E of the lead frame panel 100 after saw singulation according to one embodiment of the present invention. To electrically de-couple the leads 106 from one another, partial sawing is performed on the bottom surface of lead frame panel 100 along columns 704 and rows 708. The partial sawing cuts entirely through the metal of the connecting bars 108 of the lead frame panel 100, but not into the molding compound 700.

To separate the lead frames from one another, full sawing is performed along columns 702 and rows 706. The full sawing cuts all the way through (i) the lead frame panel 100 and (ii) the molding compound 700. In this implementation, 15 lead frames 710 are separated from one another, where each of the lead frames 710 has a 3×3 array of the leads 106. This operation also leads to some excess material 712 that may be discarded.

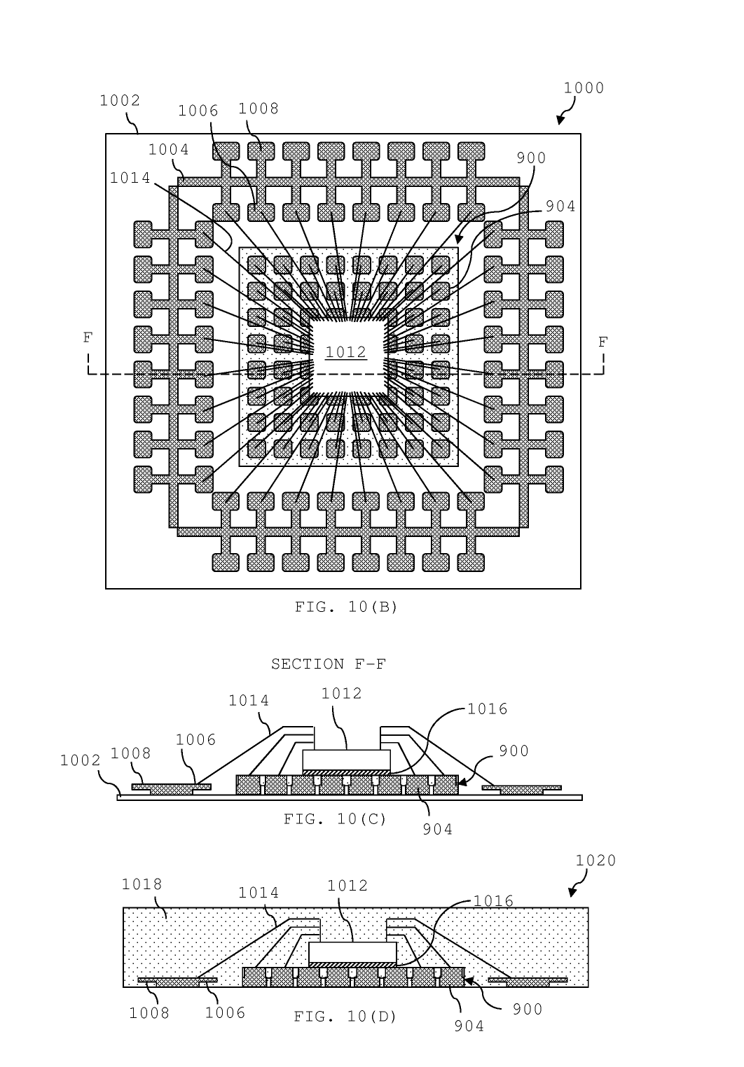

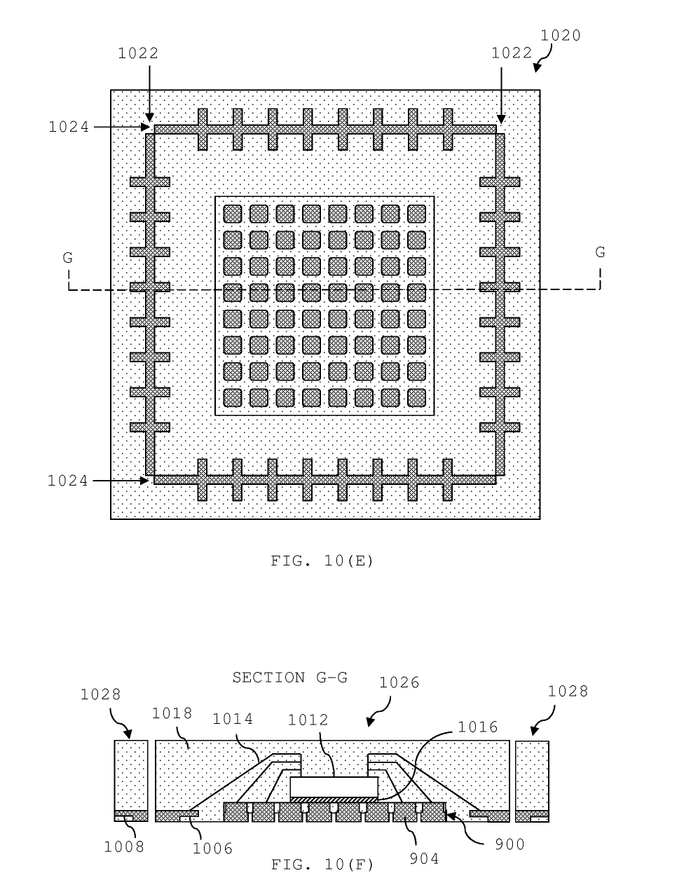

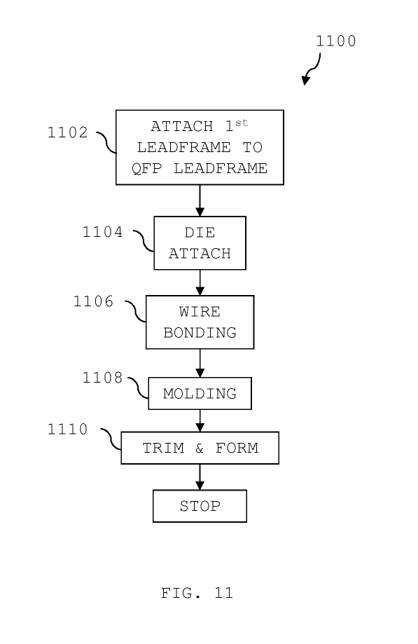

FIG. 8 shows a simplified flow diagram of a process 800 for assembling one or more surface-mount packages according to another embodiment of the present invention. The one or more surface-mount packages of the process 800 are assembled using two lead frames: a first lead frame fabricated by the process 600 in FIG. 6 and a second, conventional quad-flat no-leads (QFN) lead frame. Examples of the first and second lead frames are shown in FIGS. 9 and 10(A), respectively.

FIG. 9 shows a top view of a first lead frame 900 according to one embodiment of the present invention that may be used in the process 800 of FIG. 8. The first lead frame 900, which may be made by the process 600 of FIG. 6, has an 8×8 array of metal leads 904, which are separated by molding compound 902.

FIG. 10(A) shows a top view of one implementation of a second lead frame 1000 that may be used in the process 800 of FIG. 8. The second lead frame 1000, which is a QFN lead frame, has a pattern of metal leads that are adhered to a coverlay tape 1002. The pattern of metal leads comprises four sub-patterns 1010 forming a box-like shape, where each of the sub-patterns 1010 comprises eight metal leads 1006 oriented toward the center of the QFN lead frame 1000 and eight metal leads 1008 oriented toward the perimeter of the QFN lead frame 1000.

The eight metal leads 1006 and the eight metal leads 1008 in each of the sub-patterns 1010 are interconnected by a connecting bar 1004. Although not shown, the eight metal leads 1008 in each sub-pattern 1010 may form part of an adjacent QFN lead frame (not shown) of a multi-lead frame QFN lead frame panel, and a surface-mount package can be assembled onto each other QFN lead frame in the lead frame panel at the same time that a surface-mount package is assembled onto QFN lead frame 1000.

Referring back to FIG. 8, in step 802, the first lead frame 900 is placed at the center of the four sub-patterns 1010 of the second lead frame 1000 where it adheres to the coverlay tape 1002 of the second lead frame 1000. At step 804, a die is attached to the first lead frame 900, and at step 806, the die is wire-bonded to both of the first and second lead frames 900 and 1000.

FIGS. 10(B) and 10(C) show a top view and a cross-sectional view F-F, respectively, of the first and second lead frames 900 and 1000 after die attachment and wire-bonding. As shown, the die 1012 is attached directly onto 16 of the leads 904 of the first lead frame 900 using a die-attach film or epoxy 1016. The 16 leads 904 are inactive leads that essentially act as a die paddle and are not used for input or output connections. Further, the remaining 48 leads 904 of the first lead frame 900 (i.e., not under the die 1012) are active leads that may be used for input and/or output connections. Note that, in alternative embodiments of the present invention, the die 1012 may be attached using other techniques, including those discussed above in relation to FIGS. 4 and 5.

The die 1012 is wire-bonded via 32 bond wires 1014 to the 32 leads 1006 of the second lead frame 1000, and via 48 bond wires 1014 to the 48 active leads 904 of the first lead frame 900. Thus, in total, the die 1012 is wire-bonded to a total of 80 leads.

After wire-bonding, molding compound 1018 is applied in step 808 to encase the top of the first lead frame panel 900, the top of the second lead frame panel 1000, the die 1012, and the bond wires 1014. Further, the coverlay tape 1002 is removed from the resulting molded assembly 1020. FIG. 10(D) shows a cross-sectional view of the molded assembly 1020 after removal of the coverlay tape 1002.

In step 810, saw singulation is performed as illustrated in FIGS. 10(E) and 10(F). FIG. 10(E) shows a bottom view of the molded assembly 1020 before saw singulation, and FIG. 10(F) shows a cross-sectional view G-G of the molded assembly 1020 after saw singulation.

Full sawing is performed all the way through the molded assembly 1020 along columns 1022 and rows 1024. This sawing electrically de-couples the leads 1006 of the second lead frame 1000 from one another and from the leads 1008 of the second lead frame 1000. Further, this sawing separates the molded assembly 1020 into a surface-mount package 1026 and pieces 1028. Pieces 1028, which contain the leads 1008 of the second lead frame 1000, may be excess material that is discarded. Alternatively, each piece 1028 may be part of an adjacent surface-mount package that is assembled at the same time as surface-mount package 1026.

After sawing, the leads 1006 of the second lead frame 1000 lie along the perimeter of the surface-mount package 1026, while the leads 904 of the first lead frame 900 do not extend to the perimeter of the surface-mount package 1026. In fact, the leads 904 of the first lead frame 900 do not consume any area between the leads 1006 of the second lead frame 1000 that would affect the spacing of the leads 1006.

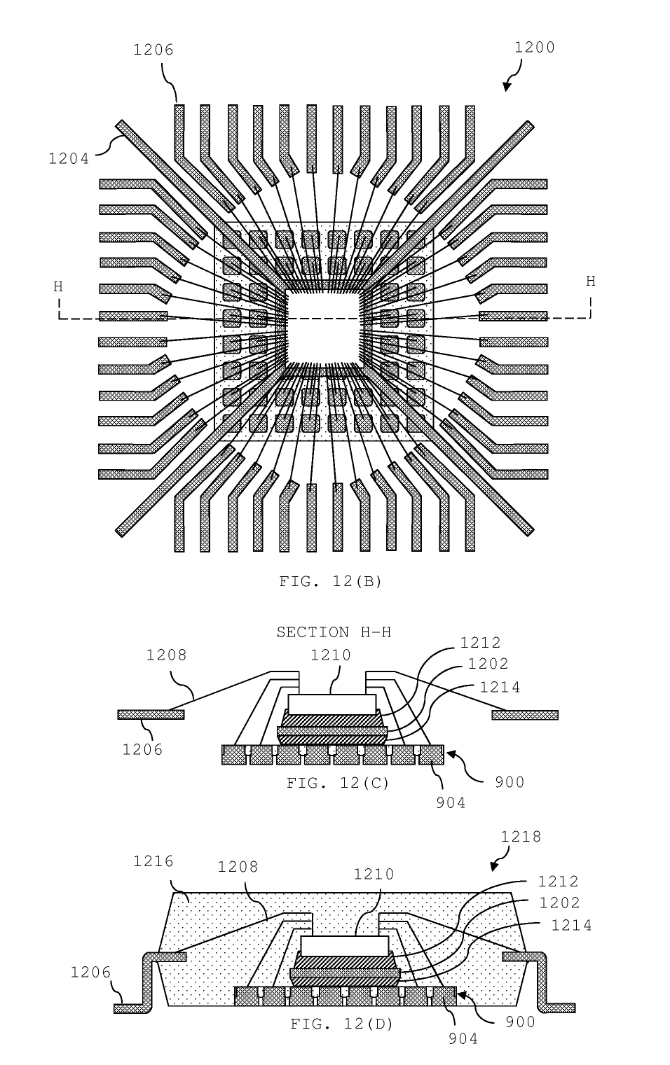

FIG. 11 shows a simplified flow diagram of a process 1100 for assembling one or more surface-mount packages according to yet another embodiment of the present invention. The one or more surface-mount packages of the process 1100 are assembled using a first lead frame, which is fabricated by the process 600 in FIG. 6, and a second lead frame, which is a conventional quad-flat package (QFP) lead frame. As an example of the process 1100, suppose that the first lead frame is the lead frame 900 shown in FIG. 9 (discussed above), and the second lead frame is the lead frame shown in FIG. 12(A).

FIG. 12(A) shows a top view of one implementation of a second lead frame 1200 that may be used in the process 1100 of FIG. 11. The second lead frame 1100, which is a QFP lead frame, has a centrally-located, square-shaped die paddle 1202 with a lead 1204 extending from each corner of the die paddle 1202 to the perimeter of the lead frame 1200. Twelve leads 1206 are positioned between adjacent leads 1204 and lie along the perimeter of the lead frame 1200. Leads 1204 and 1206 may be held together by, for example, metal connecting bars (not shown) that are cut away during later processing.

Referring back to FIG. 11, in step 1102, the first lead frame 900 is attached to one side of the die paddle 1202 of the second lead frame 1200. In step 1104, a die is attached to the other side of the die paddle 1202, and, at step 1106, the die is wire-bonded to both of the first and second lead frames 900 and 1200.

FIGS. 12(B) and 12(C) show a top view and a cross-sectional view H-H, respectively, of the first and second lead frames 900 and 1200 after die attachment and wire-bonding. As shown, the first lead frame 900 is centered underneath the die paddle 1202 of the second lead frame 1200 and attached to the die paddle 1202 using, for example, a die-attach film or epoxy 1214. As a result, the die paddle 1202 covers 16 of the leads 904 of the first lead frame 900, and the leads 1204 cover an additional eight of the leads 904 for a total of 24 covered leads. These 24 covered leads 904 are inactive leads that are not used for input or output connections, while the remaining 40 leads 904 are active leads that may be used for input and/or output connections.

A die 1210 is attached to the top of the die paddle 1202 using, for example, a die-attach film or epoxy 1212. The die 1210 is wire-bonded via 48 bond wires 1208 to the 48 leads 1206 of the second lead frame 1200, and via 40 bond wires 1208 to the 40 active leads 904 of the first lead frame 900. Thus, in total, the die 1210 is wire-bonded to a total of 88 leads.

After wire-bonding, molding compound 1216 is applied in step 1108 to encase the top of the first lead frame 900, the second lead frame panel 1200 (with the exception of part of leads 1206), the die 1210, and the bond wires 1208. The resulting surface-mount package 1218 is trimmed and formed in step 1110, and the leads 1206 are bent. Trimming may de-couple the leads 1206 from one another as described above. FIG. 12(D) shows a cross-sectional view of the surface-mount package 1218 after trimming and forming.

Note that, according to alternative embodiments of the present invention, the first lead frame 900 could be attached to the top of the die paddle 1202 of the second lead frame 1200, and the die 1210 could be attached to the leads 904 of the first lead frame 900, rather than to the die paddle 1202. In other words, the first lead frame 900 and the die 1210 could be stacked on the same side of the die paddle 1202.

As described above, lead frames of the present invention may comprise one or more interior leads that do not extend to the perimeter of the lead frame and therefore do not consume perimeter space at the expense of additional perimeter leads. As a result of these features, lead frames of the present invention may have greater numbers of leads than conventional lead frames that employ only leads that extend to the lead frame perimeter.

Planar leads such as leads 106 of FIGS. 1 and 904 of FIG. 9 may be electrically and physically coupled to a printed circuit board (not shown) by using solder paste that is printed onto the printed circuit board. In particular, to make the connection, the leads (e.g., 106/904) of the semiconductor package are aligned with the solder paste, and the solder is reflowed to melt the solder.

Lead frames and lead frame panels of the present invention are not limited to the sizes, shapes, and patterns shown in the exemplary embodiments discussed above. According to alternative embodiments, lead frames and lead frame panels of the present invention may have shapes other than a square, such as (without limitation) rectangular, circular, and hexagonal shapes.

Further, according to alternative embodiments, lead frames of the present invention may have different numbers of rows and columns of leads than the embodiments described above.

Yet further, embodiments of the present invention are not limited to having square-shaped leads arranged in an array of rows and columns. According to alternative embodiments, lead frames of the present invention may have leads with shapes other than squares and in array patterns other than arrays of rows and columns. For example, the leads may be arranged in an array of concentric circles.

Yet further, the size of leads may vary from one lead to the next within a lead frame. For example, in FIG. 9, rather than having four leads at the center of lead frame 900, a single lead could be positioned in the center of the lead frame, wherein the single lead consumes the same area as the four leads at the center of lead frame 900.

Even yet still further, one or more array locations in a lead frame might not have any lead at all.

Even yet still further, one or more active leads in a lead frame might not be wire-bonded to a die at all or might have more than one bond wire connected to it.

According to alternative embodiments of the present invention, lead frames fabricated using process 600 may be used with lead frames other than QFN and QFP lead frames. For example, lead frames fabricated using process 600 may be used with dual-flat no-lead (DFN) lead frames.

Further, the present invention is not limited to semiconductor packages that have a single semiconductor die. According to alternative embodiments, semiconductor packages of the present invention may comprise greater than one die.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

Terms of orientation such as “lower,” “upper,” “horizontal,” “vertical,” “above,” “below,” “up,” “down,” “top,” “bottom,” “right,” and “left” well as derivatives thereof (e.g., “horizontally,” “vertically,” etc.) should be construed to refer to the orientation as shown in the drawing under discussion. These terms of orientation are for convenience of description and do not require that the apparatus be constructed or operated in a particular orientation.

Unless explicitly stated otherwise, each numerical value and range should be interpreted as being approximate as if the word “about” or “approximately” preceded the value of the value or range.

It will be further understood that various changes in the details, materials, and arrangements of the parts which have been described and illustrated in order to explain the nature of this invention may be made by those skilled in the art without departing from the scope of the invention as expressed in the following claims. For example, the QFN lead frame 1000 in FIG. 10(A) and the QFP lead frame 1200 in FIG. 12(A) may have different shapes and sizes than those shown and different numbers of leads than those shown. In addition, the die paddle 1202 of QFP lead frame 1200 may have another shape.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the present invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

The embodiments covered by the claims in this application are limited to embodiments that (1) are enabled by this specification and (2) correspond to statutory subject matter. Non-enabled embodiments and embodiments that correspond to non-statutory subject matter are explicitly disclaimed even if they fall within the scope of the claims.

1. A packaged semiconductor device, comprising:
an array lead frame comprising a two-dimensional array of leads having a subset of interior leads located in an interior of the array that do not extend to a perimeter of the array;
a semiconductor die mounted over the subset of interior leads;
first bond wires that electrically connect bond pads on a surface of the semiconductor die to selected ones of the leads of the array.

2. The packaged semiconductor device of claim 1, wherein the two-dimensional array comprises leads arranged in three or more rows and three or more columns, such that the subset of the interior leads are arranged in one or more rows and one or more columns.

3. The packaged semiconductor device of claim 1, wherein:
the two-dimensional array of leads comprises a subset of perimeter leads that extend to the perimeter of the lead frame;
at least one of the first bond wires is attached to the semiconductor die and to one of the interior leads; and
at least one other first bond wire is attached to the semiconductor die and to one of the perimeter leads.

4. The packaged semiconductor device of claim 1, further comprising an encapsulation material that at least partially covers the semiconductor die and the first bond wires.

5. The packaged semiconductor device of claim 1, further comprising:
a second lead frame comprising perimeter leads that extend along a perimeter of the second lead frame, wherein the perimeter leads surround and are spaced from the leads of the two-dimensional array of leads; and
second bond wires that electrically connect the semiconductor die and the perimeter leads.

6. The packaged semiconductor device of claim 5, wherein the two-dimensional array comprises leads arranged in three or more rows and three or more columns, such that the subset of leads located in the interior of the array are arranged in one or more rows and one or more columns.

7. The packaged semiconductor device of claim 5, wherein the second lead frame is attached to the array lead frame using molding compound.

8. The packaged semiconductor device of claim 5, further comprising an encapsulation material that at least partially covers the semiconductor die and the first and second bond wires.

9. The packaged semiconductor device of claim 5, wherein the second lead frame is a quad-flat no-leads lead frame.

10. The packaged semiconductor device of claim 5, wherein the second lead frame comprises a die paddle, the semiconductor die is mounted to the die paddle, and the die paddle is mounted over the subset of interior leads.

11. The packaged semiconductor device of claim 10, wherein the semiconductor die is attached to the die paddle with a first adhesive and the die paddle is attached to the subset of interior leads with a second adhesive material.

12. The packaged semiconductor device of claim 5, wherein the second lead frame is a quad-flat package lead frame.

13. A semiconductor device, comprising:
a perimeter lead frame having perimeter leads along a perimeter of the lead frame;
an array lead frame comprising a two-dimensional array of interior leads that are surrounded by and spaced from the perimeter leads;
a semiconductor die mounted over one or more of the interior leads;
first bond wires that electrically connect first bond pads on a surface of the semiconductor die to selected ones of the interior leads;
second bond wires that electrically connect second bond pads on the surface of the semiconductor die with respective ones of the perimeter leads; and
an encapsulation material that at least partially covers the semiconductor die and the first and second bond wires.

14. A semiconductor device, comprising:
a perimeter lead frame having perimeter leads along a perimeter of the lead frame, and a die paddle surrounded by the perimeter leads;
an array lead frame comprising a two-dimensional array of interior leads, wherein the interior leads are surrounded by and spaced from the perimeter leads;
a semiconductor die mounted over the die paddle;
first bond wires that electrically connect first bond pads of the semiconductor die with respective ones of the interior leads;
second bond wires that electrically connect second bond pads of the semiconductor die with respective ones of the perimeter leads; and
an encapsulation material that at least partially covers the semiconductor die and the first and second bond wires.
